(19) United States
(12) Patent Application Publication
(10) Pub. No.: US 2021/0006038 A1
(43) Pub. Date: Jan. 7, 2021

(54) OPTICAL FREQUENCY COMB SETUP AND USE OF AN EXTERNAL CAVITY FOR DISPERSION COMPENSATION AND FREQUENCY TUNING

(71) Applicant: IRSWEEP AG, Stäfa (CH)

(72) Inventors: Johannes David HILLBRAND, Feldkirch (AT); Pierre JOUY, Zürich (CH); Jérôme FAIST, Zürich (CH); Markus MANGOLD, Zürich (CH); Christopher TCHERVENKOV, Zürich (CH)

(73) Assignee: IRSWEEP AG, Stäfa (CH)

(21) Appl. No.: 16/770,185

(22) PCT Filed: Dec. 5, 2018
(86) PCT No.: PCT/EP2018/083624

§ 371 Date: Jun. 5, 2020

(30) Foreign Application Priority Data
Dec. 7, 2017 (CH) 01489/17

(51) Int. Cl. H01S 5/14; H01S 5/34; H01S 3/08; H01S 3/105; H01S 3/101; H01S 5/024; H01S 5/10

(52) U.S. Cl. CPC H01S 5/14; H01S 5/3402; H01S 3/0809; H01S 5/1096; H01S 3/101; H01S 5/02469; H01S 3/105

(57) ABSTRACT

An optical frequency comb setup including a semiconductor cascade laser drivable by a laser driver, emitting a laser beam through an end facet of the semiconductor cascade laser with a frequency comb with at least two given individual emission frequencies, repetition frequency, carrier envelope offset frequency shows improved comb stability and/or comb formation and/or comb bandwidth. This is achieved by an external cavity added outside of the cavity of the semiconductor cascade laser, having a reflective element with a mirror surface reflecting the at least two individual emission frequencies being arranged in a relative distance to the end facet allowing to adapt repetition frequency and/or carrier envelope offset frequency and/or the dispersion seen by the light in the optical frequency comb setup.

### TECHNICAL FIELD

The present invention describes an optical frequency comb setup comprising a semiconductor cascade laser drivable by a laser driver, emitting a laser beam through an end facet of the semiconductor cascade laser with a frequency comb with at least two given individual emission frequencies, repetition frequency, carrier envelope offset frequency and use of an external cavity arranged in an optical frequency comb setup.

### STATE OF THE ART

Optical frequency combs have revolutionized many applications. Nowadays, they are used for optical frequency measurement. The most precise clocks are realized with optical clocks using frequency combs. Frequency combs are used for distance measurement. Reliable time/frequency transfer in optical fibers and free-space has been shown. They are used for optical waveform generation and low-noise microwave generation. They are used in low noise frequency synthesis and have revolutionized manufacturing and atto-second sciences though short pulse generation. Another important application of frequency combs is their use in optical sensing applications.

Optical sensing solutions in the mid-infrared range, are commercially interesting in different applications, for example to perform absorption spectroscopy, because the mid-infrared range comprises strong fingerprint-like absorption features of most molecules. There is a large demand for optical detecting methods, such as optical (multi-) heterodyne detection setups, offering broad spectral coverage and speed in combination with high brightness. Optical frequency comb setups are used in different fields commercially. For example, in the mid-infrared frequency regime, frequency combs are useful sources of radiation for detecting molecular finger-prints, because many molecules have strong rotational and vibrational resonances in this frequency regime. Multi-heterodyne spectroscopy based on two frequency combs, which is also known as dual-comb spectroscopy, allows performing broadband spectroscopy with a broad spectral coverage, a high frequency resolution, and high signal-to-noise ratios. In dual-comb spectroscopy, two frequency combs are directed onto a detector, and the heterodyne beating between different pairs of lines is detected.

Such dual frequency comb setups 0 can comprise at least two optical frequency comb setups 1, 1′ consisting of electrically-pumped semiconductor cascade laser structures 11, 11′ emitting optical frequency combs 12, 12′. Optical frequency combs 12, 12′ are beams of coherent light whose spectrum is comprised of numerous equidistant lines. Each individual emission frequency (fₙ) of a frequency comb 12, 12′ can be described mathematically by the formula: fₙ=f_{ceo}+n*fᵣₑₚ, where f_{ceo} is the carrier envelope offset frequency, fᵣₑₚ is the repetition frequency (mode spacing) and n is an integer.

An embodiment of a dual-comb and multi-heterodyne detection scheme according to the prior art is depicted in FIGS. 1a and 1b. The dual frequency comb setup 0 here comprises two cascade laser structures 1, 1′, with a first and a second semiconductor cascade laser 11, 11′. Both semiconductor cascade lasers 11, 11′ are connected to laser drivers 10, 10′, which are operating the optical frequency combs 11, 11′ to generate emission as explained above.

In this setup 0 one laser beam is passing through a sample 3 before entering a combining and deflecting means 2 and a detector 4. The other laser beam is deflected through the combining and/or deflecting means 2 into the detector 4, without passing the sample 3. The dual frequency comb setup 0 builds an optical path in which all components are placed. Both laser beams are superimposed on the detector 4 and a beating signal at the difference frequency of the emission frequencies of the frequency combs is generated on the detector 4. In another embodiment, the sample 3 can be placed after the combining and deflecting means 2 in the optical path, so that both optical frequency combs 12, 12′ are combined and pass through the sample 3. All components are placed in the optical path. Connected to the detector 4 is a heterodyne signal processing unit, which subsequently analyzes said signal to generate a meaningful analysis of the heterodyne signal for the user. The optical signals are down-converted in the multi-heterodyne setup to the RF-domain and therefore need to be processed in the heterodyne signal processing unit.

Here the optical frequency combs 12, 12′ are generated by using optical frequency comb setups 1, 1′ with semiconductor cascade lasers 11, 11′ in form of quantum cascade laser (QCL) or interband cascade laser (ICL). The nonlinear optical process responsible for generating the comb in semiconductor cascade lasers 11, 11′ only works efficiently if the inherent dispersion of the laser can be compensated. Furthermore, both fᵣₑₚ and f_{ceo} are affected by environmental factors like the temperature and thus change over time. The optical signals of the optical frequency combs 12, 12′ of both semiconductor cascade lasers 11, 11′ are down-converted in the multi-heterodyne setup to the RF-frequency-domain and therefore need to be processed in the detector 4 or connected to a heterodyne signal processing unit. Heterodyne detection is very common in many domains, has been extensively used in dual-comb setups and details of frequency detection and heterodyne signal processing can be looked up elsewhere.

The repetition frequency fᵣₑₚ of the combs 12, 12′ depends strongly on the cavity length of the used semiconductor cascade laser 11, 11′. The cavity of commercially available femtosecond frequency combs is considerably longer than the cavity of QCL combs and its length can be modified, what is known from DE 19911103. It allows to stabilize repetition frequency and offset frequency of femtosecond combs. The technique presented requires the modification of the cavity length of the laser. Since the cavity of QCL combs consists of cleaved semiconductor material here, its length cannot be changed and the aforementioned technique cannot be applied. US020130121362 shows an optical frequency comb with at least one cascade laser structure for different applications. There is no teaching in US020130121362 concerning correction of dispersion of the optical frequency comb setup. The person skilled in the art cannot derive from the document, if the introduced Graphene saturable absorbers or other features allow adapting repetition frequency and/or carrier envelope offset frequency and/or the dispersion of the optical frequency comb setup.

In Andreas Hugi, Single-mode and Comb Operation of Broadband Quantum Cascade Lasers, PhD thesis, ETH Zurich, 2013, it has been shown that the repetition frequency of QCL combs can be stabilized using the pump current of the laser. However, changes of the pump current do not only affect fᵣₑₚ, but also f_{ceo}. Thus, independent tuning of both frequencies fᵣₑₚ, f_{ceo} is not possible using only the pump current.

Prior work by Gustavo Villares, et al. “On-chip dual-comb based on quantum cascade laser frequency combs.” Applied Physics Letters 107.25 (2015): 251104, demonstrated that control of both fᵣₑₚ and f_{ceo} of a QCL is possible by integrating micro-heaters beside the QCL chip, allowing a controlled heating of the semiconductor cascade laser 11, 11′. While the presented micro-heaters provide control of both fᵣₑₚ and f_{ceo}, this method is limited by the diffusion time of the heat produced by the heaters in the semiconductor cascade laser 11, 11′. This work was done in the specific case of having the two laser combs integrated on the same chip. The more general idea of using the temperature as another mean to tune frep and fceo has been used in the thesis of Andreas Hugi as well.

Furthermore, it has been shown that QCL frequency combs can be stabilized with a separate metrological difference-frequency-generated (DFG) comb source, published in Francesco Cappelli, et al. “Frequency stability characterization of a quantum cascade laser frequency comb.” Laser & Photonics Reviews 10.4 (2016): 623-630. This frequency stabilization scheme requires a large and expensive additional DFG comb source. This is not compatible with the commercial exploitation of QCL combs, since one of their main advantages is their compactness.

From Yves Bidaux et al., “Plasmon-enhanced waveguide for dispersion compensation in mid-infrared quantum cascade laser frequency combs”, Opt. Lett. 42, 1604-1607 (2017) it is known that the dispersion of QCL combs is so far controlled via material composition and waveguide design of the QCL chips. Dispersion control via material composition or waveguide design is very limited, because material composition and waveguide design strongly affect the laser operation performance, i.e. the emission wavelength and power. The dispersion of the laser is the property of having a refractive index which varies as a function of the emission wavelength. If the dispersion of a laser is too big, it prevents it from operating in the comb regime or can as well degrade the frequency stability of the comb. So far, no possibility to modify the dispersion of a cascade laser without changing the material composition of the semiconductor chip was demonstrated. Furthermore, no scheme enabling independent control of both the repetition frequency fᵣₑₚ and the offset frequency f_{ceo} of QCL respectively ICL combs has been demonstrated so far. Currently, in dual frequency comb setups 0 with frequency comb setups 1, 1′, fceo and frep are not individually controlled. Therefore, high detection and acquisition bandwidth are needed for a given spectrum, which makes the spectrometers more expensive.

Frequency comb operation has been as well demonstrated in ICLs for example in work from K. Ryczko et al., “Optimizing the active region of interband cascade lasers for passive mode-locking”, AIP Advances 7, 015015 (2017). The problematics discussed above apply to ICLs as well.

### DESCRIPTION OF THE INVENTION

The object of the present invention is to create an optical frequency comb setup or spectrometer with at least one cascade laser structure reaching an improved Optical frequency comb setup behaviour leading to more precise measurement results, in particular for processing multi-heterodyne signals.

We want to allow a certain control over the key parameters of the comb after the laser has been fabricated and mounted. Controlling the dispersion allows to have more lasers operating in the comb regime and to improve the stability of the lasers already operating in the comb regime and controlling frep and fceo allows to adapt those parameters to the needs of the optical frequency comb setup.

In the case of a dual comb spectroscopy setup, we want to correct or tune the frep and fceo so that the multiheterodyne signal can be entirely in the bandwidth of the detector and of the acquisition apparatus. Fceo cannot be controlled during the design or the fabrication of the lasers. Frep can be controlled during the fabrication of the laser but with a very large uncertainty (several MHz in the best case scenario at the moment). But especially for dual comb spectroscopy setups having a control on the order of MHz and below on frep is necessary. It is a very restrictive problem for frequency comb spectroscopy that frep and fceo of nominally identical lasers can strongly deviate from one to another. In practice, it means that several lasers have to be tested to be able to pair two lasers together to do dual comb spectroscopy. Controlling frep and fceo allows to use two lasers which originally have a slightly different length to still have matching frep and to adjust the fceo of a laser to match the one of the other laser.

Improving the dispersion allows to increase the driving parameter range (current, temperature) on which the laser is operating in comb regime and even could turn a laser which does not emit in comb regime into a laser which does. This makes more cascade laser structures usable for frequency comb spectroscopy and allows for a bigger freedom to overlap the spectra of the two lasers, since changing the temperature and the current changes the number of lines and the frequency of emission.

This problem is solved by introducing means of compensation of dispersion of the used semiconductor cascade lasers and at the same time means of tuning the frequencies of the optical frequency comb, more specifically, to find a simplified and cheap solution for independent control of f_{ceo} and fᵣₑₚ, by avoiding heating setups, other expensive additional structures and without amending manufacturing process of QCLs or ICLs as known from prior art.

The clou is an external optical element, which allows modifying the dispersion without changing the laser characteristics. With the possibility to modify the dispersion of a laser externally, the performance of QCL/ICL frequency combs can be improved after the chip manufacturing process and independent from the manufacturing process.

Using an external cavity allows to improve the comb stability/formation/bandwidth respectively by control of the dispersion and adjustment of frep and fceo in order to control the comb parameters.

Furthermore, the here described solution using an external cavity simplifies the manufacturing of the frequency comb setup, if integrated on-chip using for example a piezo element or MEMS (Microelectromechanical system) device. The new scheme is essential for commercialised spectrometers using QCL or ICL frequency combs.

### BRIEF DESCRIPTION OF THE DRAWINGS

A preferred exemplary embodiment of the subject matter of the invention is described below in conjunction with the attached drawings.

FIG. 1a shows a schematic view of a dual optical frequency comb setup, comprising two optical frequency comb setups according to prior art, while

FIG. 1b shows an amplitude vs. frequency diagram of a dual optical frequency comb setup according to prior art.

FIG. 2 shows an optical frequency comb setup with external cavity in a schematical view with fixed distance between end facet and mirror surface, while

FIG. 3 shows a schematic view of an optical frequency comb setup affixed in a linear translation mechanism for adjustment of distance d.

FIG. 4 shows a schematic view of a cascade laser structure affixed in a linear translation mechanism comprising an electromechanical actuator.

FIG. 5 a) shows a schematic view of emission of a modified laser beam using one external cavity, while

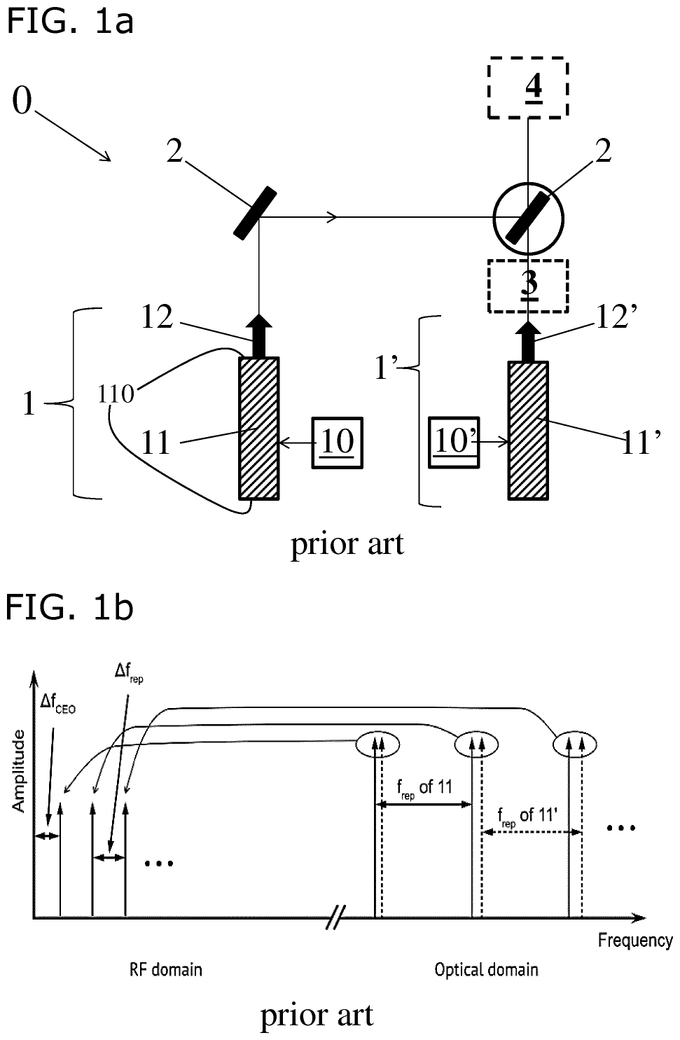

b) shows a schematic view of emission of two modified laser beams using two external cavities attached to one semiconductor cascade laser.

### DESCRIPTION

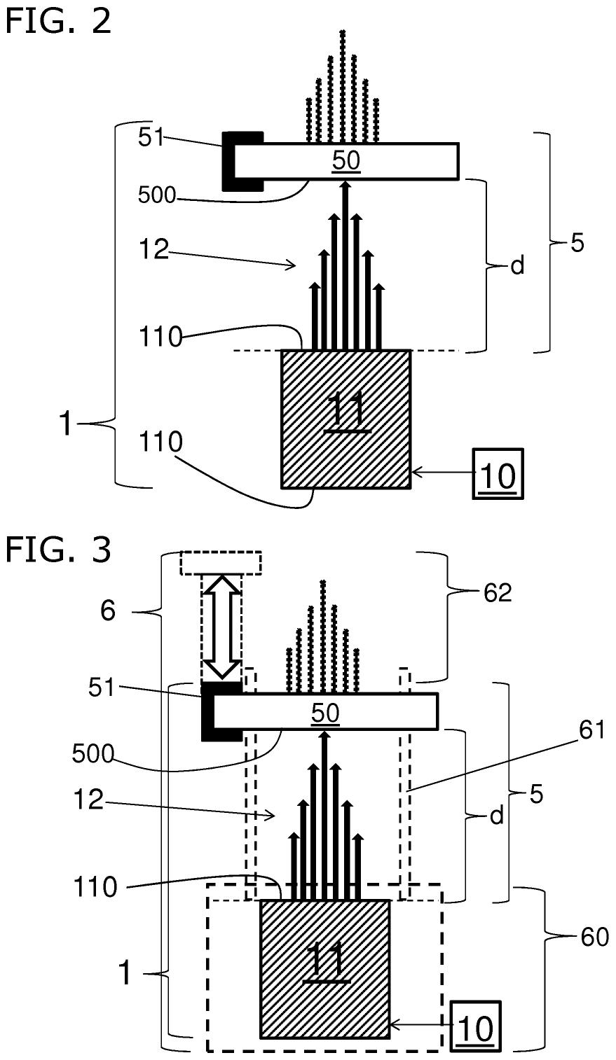

Examples of optical frequency setups 1 will be described starting with FIG. 2 in the following. Such optical frequency setups 1 comprise a semiconductor cascade laser structure 11 and a laser driver 10. If a dual frequency comb setup is build, it further comprises a second frequency comb setup 1′ with a semiconductor cascade laser 11′ and a laser driver 10′, not depicted in FIG. 2, which can be identical in construction as the cascade laser structure 1.

Here the used semiconductor cascade laser structures 11, 11′ are especially quantum cascade lasers (QCL) or an interband cascade lasers (ICL), which are based on semiconducting gain media, where optical gain is achieved by stimulated emission of intersubband transitions respectively interband transitions. Such semiconductor cascade laser 11, 11′ are operating in mid- to far-infrared spectral region, with central wavelength above 3 microns and a person skilled in the art knows different QCLs and ICLs and how to provide such semiconductor cascade laser 11. The cavity of the QCL or ICL is formed like a chip, which can be manufactured by cheap mass production.

The semiconductor cascade laser 11 is operated by the laser driver 10 emitting a laser beam with an optical frequency comb (12) with given central wavelength and individual emission frequencies (fn), repetition frequency (frep), and carrier envelope offset frequency (fceo). The dispersion is an intrinsic property of the optical frequency comb setup (1), but it does not show in the optical frequency comb (12). It helps the formation of the optical frequency comb (12) if the dispersion of the optical frequency comb setup (1) is low.

The first laser beam with frequency comb 12 exits through an end facet 110 of a cavity formed between the two end facets 110 of the semiconductor cascade laser 11. The end facet 110 can be partially reflective in the frequency range of the used semiconductor cascade laser 11, reflecting a part of the emitted light back into the waveguide of the semiconductor cascade laser 11.

The end facet 110 is a flat surface of semiconducting solid, which is at least partly reflective, while the reflectivity of the end facet 110 is adjustable by an antireflection coating or a high-reflection coating placed on the outside surface of the end facet. The end facet 110 can also be coated with a dispersion compensation coating.

For compensation of dispersion and independent control of f_{ceo} and fᵣₑₚ an external cavity 5, comprising a reflective element 50 affixed with holding means 51 in a distance d, is defined between a mirror surface 500 and outside surface of the end facet 110.

The external cavity is coupled outside of the cavity of the semiconductor cascade laser 11. Values of the distance d can be from the order of a micrometer to the order of a meter.

A more complex part of the optical frequency comb setup 1 is depicted in FIG. 3, based on the optical frequency comb setup 1 of FIG. 2, showing a linear translation mechanism 6. The linear translation mechanism 6 comprises a cascade laser mount 60, an optional guiding device 61 and a mechanical actuator 62. The cascade laser mount 60 and the holding means 51 of the reflective element 50 are connected to the guiding device 61, in order to make the distance d between surface of the end facet 110 and the mirror surface 500 adjustable. In another embodiment holding means 51 and cascade laser mount 60 are separated and not connected to the guiding device 61. The relative linear position of the reflecting element 50 can be changed by linear translation of the holding means 51 relative to the semiconductor cascade laser structure 11 respectively the end face 110 by adjusting the mechanical actuator 62. The mechanical actuator 62 can be a micrometer screw, which is schematically indicated by broken lines.

The external cavity 5 is added outside of the cavity of the semiconductor cascade laser 11. With the linear translation mechanism 6 the distance d in direction of the exiting laser beam comb 12 between reflective element 50 with mirror surface 500 and the end facet 110 can be adjusted by either movement of the reflective element 50 fixed by the holding means 51 or movement of the semiconductor cascade laser 11 respectively its end facet 110 in direction of the laser beam in such a way, that the elongation of the external cavity 5 respectively the linear position of the reflective element 50 relative to the end facet 110 leads to modification of repetition frequency frep and/or carrier envelope offset frequency f_{ceo} and/or dispersion.

While the semiconductor cascade laser structure 11 is emitting the optical frequency comb 12, the dispersion and at the same time frequencies f_{ceo} and fᵣₑₚ can be controlled by adjusting distance d. The quality of measurements, if such an optical frequency comb setup 1 is used in a spectroscopy setup can therewith be improved.

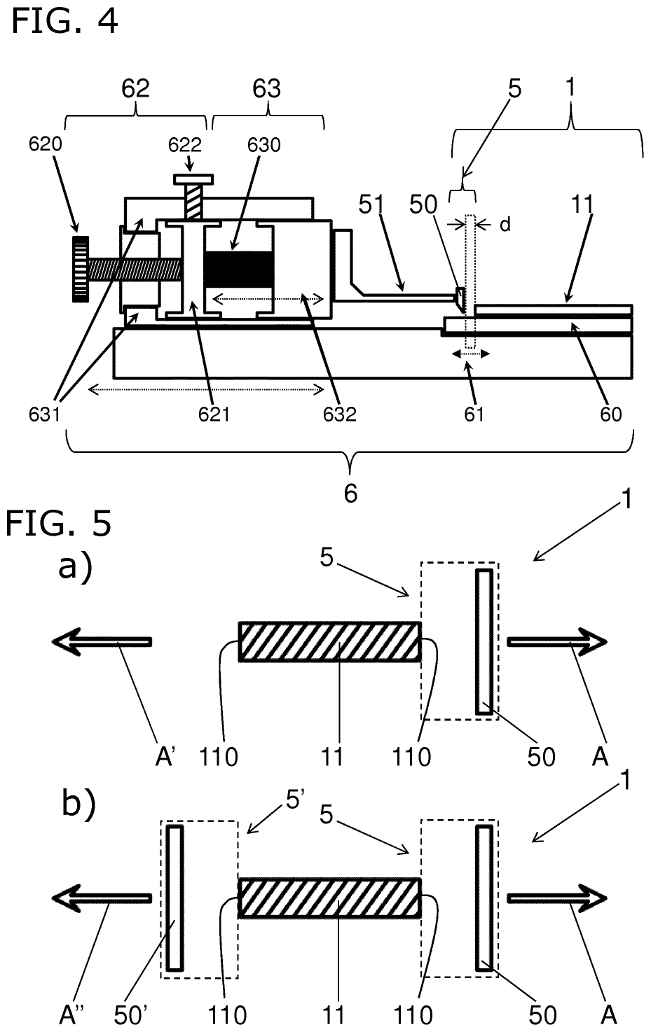

FIG. 4 shows a schematic setup of an optical frequency comb setup 1 with the semiconductor cascade laser 11, without the laser driver 10 and with the linear translation mechanism 6 in another embodiment. The optical frequency comb setup 1 is mounted on the cascade laser mount 60. The distance d between reflective element 50 and the end facet 110 and therewith the external cavity 5 are depicted. The possible elongation of the external cavity 5 is indicated with the double arrow.

The holding means 51 of the here wedge-like formed reflective element 50 is composed of a tip 51, which is connected to the mechanical actuator 62 and an electromechanical actuator 63.

The mechanical actuator 62 comprises a micrometer screw 620 and a sliding element 621, which are connected to the holding means 51 for reaching the linear movement of the mechanical actuator 62 and the holding means 51 with reflective element 50 relative to the semiconductor cascade laser 11 along a mounting plate 61, which is defined here as guiding device 61. The micrometer screw 620 allows to move the sliding element 621. A blocking screw 622 as possible blocking means allows to fix the position of the first sliding element 621. With the mechanical actuator 62 a coarse linear movement can be done with an accuracy of the order of a micron.

The electromechanical actuator 63 comprises a piezo element 630. Optionally the piezo element 630 is arranged in a piezo element housing 631, a second sliding element 632 and a non-depicted steering electronics, which generates a high voltage.

The piezo element housing 631 is mounted on the same mounting plate 61 as the semiconductor cascade laser 11. Here the mounting plate 61 is used as well as a heatsink for the semiconductor cascade laser 11 and is temperature controlled. Suitable temperature control means are known, but not depicted here. In the piezo element housing 631, two sliding elements are placed. The first one is attached to the back of the housing with springs in order to have a restoring force toward the back of the housing. The two ends of the piezo element 630 are glued on each sliding element 621, 632. By applying a voltage on the piezo element 630, the second sliding element 632 can be displaced with a precision of a few nanometers. Therewith a fine linear movement can be reached. The stepwise resolution of the linear movement due to the electromechanical actuator 63 should be in a range below one micron. The relative position of the reflective element 50 is controlled by the piezoelectric actuator 63 in a closed loop operation. Depending on the distance d between reflective element 50 and the end facet 110, the inherent dispersion of the semiconductor cascade laser 11 can be decreased to values considerably smaller than 1000 fs².

In another embodiment of the optical frequency comb setup 1, the linear translation mechanism 6 can be provided by a Microelectromechanical systems or MEMS device, which can provide the linear coarse and fine adjustment in one device. In such a MEMS device the cascade laser structure 11, the linear translation mechanism 6 with cascade laser mount 60, the electromechanical actuator 63 and the parts of the external cavity 5 can be integrated or connected to the same mounting plate 61 or can be separated on different mounts. Such a MEMS device also needs a steering electronics for controlling the distance d by either changing the linear position of the semiconductor cascade laser 11 or the reflective element 50.

In the following part, some possible specialities usable in all embodiments of the Optical frequency comb setup 1 are described. For example, the reflective element 50 can be formed of a single or multilayer of sufficient reflective material respectively materials. Beside a reflective element 50 of gold, a preferred choice is a block of a semiconducting material with direct band gap, in particular Gallium Arsenide, Silicon, indium phosphide or Germanium. For example reflective element 50 in form of a mirror of a cleaved piece of GaAs is placed in distance d from the end facet 110 of the semiconductor cascade laser 11. The reflective element 50 should be partly reflective in the wavelength region of QCLs and ICLs 11.

The outside surface of the end facet 110 and therewith the reflectivity of the laser facet 110 can be modified by an optical facet coating, comprising at least one layer directly coated on the outside surface of the end facet 110. The “natural” reflectivity of the laser facet 110 is around 30%. This value can be adjusted by either a high-reflection coating to increase this value or an anti-reflection coating to decrease it. In practice the coating of the outside surface of the end facet 110 can be done with single or multiple layers of Al2O3, SiO2, Si, Ge, YF3, BaF2, Au, Ti or other material proven to work for facet coatings of cascade lasers.

Not depicted in the Figures, but due to the divergence of the laser beam of semiconductor cascade lasers 11, beam shaping elements can be placed in the basic external cavity 5. Possible beam shaping elements are lenses or curved mirrors, which are placed between end facet 110 and the reflective element 50 in the optical path.

In other embodiments, at least one dispersive element can be placed inside the external cavity 5, between end facet 110 and mirror surface 500. Possible dispersive elements are a prism, a reflective grating, a phase grating or a multilayer element.

An additional dispersive coating layer can be provided on the mirror surface 500 of the reflective element 50 and/or the outside surface of the end facet 110 and/or the surfaces of beam shaping or dispersive elements placed between end facet 110 and the reflective element 50, for dispersion compensation and frequency stabilization of QCL/ICL frequency combs 12.

This dispersive coating can for example form an external Gires-Tournois Cavity. Possible coating layer are dielectric and metallic coatings, which are designed to change the dispersion of the external cavity 5.

Such coatings can comprise in particular Al2O3/SiO2, YF3/Ge, . . . layers and can as well be only partly reflective.

The dispersion of the whole optical frequency comb setup 1 is then the sum of the dispersion of the semiconductor cascade laser 11 chip dispersion and the dispersion of every element and coatings placed between the laser end facet 110 and the mirror surface 500. It includes any beam shaping element, any dispersive element and any coatings on the laser end facet 110, on the mirror surface 500 and on the beam shaping and dispersive element. By implementation with locally fixed reflective element 50 and a coating layer, the reflective element can be used to control f_{ceo} and fᵣₑₚ.

Different beam exiting modes are possible in an optical frequency comb setup 1 in different directions after passing at least one external cavity. For example as presented in the schematic drawing of FIG. 5a). A frequency comb laser beam A can exit the semiconductor cascade laser 11 after passing the external cavity 5 in a first direction, while a frequency comb laser beam A′ exits the semiconductor cascade laser 11 through a second end facet 110 at the opposite side of the semiconductor cascade laser 11 in an opposite direction after passing the internal cavity of the semiconductor cascade laser 11.

In FIG. 5b) another optical frequency comb setup (1) is depicted, comprising two external cavities 5, 5′. Beside the first external cavity 5 at one side of the semiconductor cascade laser 11, a second external cavity 5′ is attached, comprising a second end facet 110 and a second reflective element 50′ on the opposite side of the first external cavity 5. While a first frequency comb laser beam A exits through the first reflective element 50 in a first direction, a second frequency comb laser beam A″ passes through the second reflective element 50′ in a second direction, opposite to the first. Both frequency comb laser beams A, A″ were modified by both external cavities 5, 5′.

Best results can be achieved if the external reflective element 50 is in very close proximity to the cascade laser end facet 110, such that the optical path of the laser cavity that is outside the semiconductor chip is smaller than the path within the laser chip. Improved suitable distance d between the external reflective element 50 and the cascade laser end facet 110 is preferred less than 0.1 mm, most preferred between 5 microns and 100 microns. In such a setup, the reflective element 50 is in such a close proximity to the laser end facet 110, such that the optical path outside the semiconductor chip 11 is much smaller than the optical path inside the semiconductor chip 11. Also in that configuration, the external cavity can be used to adjust fᵣₑₚ and/or f_{ceo} and/or the dispersion of the frequency comb setup. This is either achieved by a dispersive coating on the mirror surface, or just by choosing the mirror position in a way that the external cavity positively influences fᵣₑₚ and/or f_{ceo} and/or the dispersion of the overall frequency comb setup.

### LIST OF REFERENCE NUMERALS

0 Dual optical frequency comb setup

1 Optical frequency comb setup
10 laser driver
11 semiconductor cascade laser (QCL, ICL)
   110 end facet
12 optical frequency comb

2 beam combiner/combining and deflecting means

3 sample

4 detector/signal processing unit

5 External Cavity (outside the laser cavity)
50 Reflective element (mirror, single or multi layer)
   500 mirror surface
51 holding means of reflective element (tip, glued)
d distance between mirror surface 500 and surface of end facet 110

6 linear translation mechanism
60 cascade laser mount
61 guiding device/mounting plate
62 mechanical actuator
   620 micrometer screw
   621 sliding element
   622 blocking screw
63 electromechanical actuator
   630 piezo element
   631 piezo element housing
   632 sliding element

1-24. (canceled)

25. An optical frequency comb setup comprising a semiconductor cascade laser drivable by a laser driver, emitting a laser beam through an end facet of the semiconductor cascade laser with a frequency comb with at least two given individual emission frequencies, repetition frequency, carrier envelope offset frequency,
wherein an external cavity is added outside of a cavity of the semiconductor cascade laser, comprising a reflective element with a mirror surface reflecting the given at least two individual emission frequencies being arranged in a relative distance (d) to the end facet (110) allowing to adapt repetition frequency (frep) and/or carrier envelope offset frequency (fceo) and/or the dispersion seen by the light in the optical frequency comb setup (1).

26. The optical frequency comb setup according to claim 25, wherein the semiconductor cascade laser and/or the reflective element are arranged in a linear translation mechanism such that the relative distance between the end facet and the mirror surface is adjustable by either movement of the reflective element fixed by holding means or movement of the semiconductor cascade laser and the end facet in the direction of the laser beam in such a way, that elongation of the external cavity respectively the relative linear position of the reflective element to the end facet leads to modification of the repetition frequency and/or the carrier envelope offset frequency and/or the dispersion.

27. The optical frequency comb setup according to claim 26, wherein the linear translation mechanism comprises a cascade laser mount and a mechanical actuator for coarse or fine adjustment of distance.

28. The optical frequency comb setup according to claim 27, wherein the mechanical actuator is able to move a sliding element, which movability is lockable by a blocking member, allowing to fix the position of the sliding element.

29. The optical frequency comb setup according to claim 28, wherein the mechanical actuator is formed by a micrometer screw.

30. The optical frequency comb setup according to claim 26, wherein the linear translation mechanism comprises a cascade laser mount, an electromechanical actuator and a steering electronics for fine adjustment of distance.

31. The optical frequency comb setup according to claim 30, wherein the electromechanical actuator comprises a piezo element.

32. The optical frequency comb setup according to claim 30, wherein the electromechanical actuator is a MEMS device operable by a steering electronics, usable to adjust the relative distance between the reflective element and the end facet in a coarse and fine adjustment.

33. The optical frequency comb setup according to claim 25, where the distance between reflective element and the end facet is such that the optical path outside the semiconductor chip is smaller than the optical path inside the semiconductor chip, at most half the length of the semiconductor chip.

34. The optical frequency comb setup according to claim 25, wherein the semiconductor cascade laser and/or the reflective element of the external cavity is mounted on a mounting plate, which is additionally used as a heatsink for the at least one semiconductor cascade laser, which is temperature controlled by a temperature controller.

35. The optical frequency comb setup claim 25, wherein the reflective element is partially reflective in the frequency range of the semiconductor cascade laser, allowing control of light fed back into the semiconductor cascade laser and/or exiting the external cavity.

36. The optical frequency comb setup according to claim 35, wherein the reflective element comprises at least one semiconducting material, in particular Gallium Arsenide, Silicon, indium phosphide or Germanium.

37. The optical frequency comb setup according to claim 25, wherein an additional coating layer or multilayer in form of a dielectric and/or metallic dispersive coating is provided on the mirror surface of the reflective element and/or the outside surface of the end facet and/or surfaces of beam shaping or dispersive elements placed between end facet and the reflective element, for dispersion compensation and frequency stabilization.

38. The optical frequency comb setup according to claim 25, wherein the outside surface of the end facet and therewith the reflectivity of the laser facet is modified by optical facet coating, comprising at least one electrically non-conducting layer directly coated on the surface of the end facet.

39. The optical frequency comb setup according to claim 25, where the distance between the reflective element and the end facet is most preferred between 5 microns and 100 microns.

40. The optical frequency comb setup according to claim 25, wherein beam shaping elements are placed in the external cavity, between the end facet and the reflective element in the optical path, comprising in particular at least one lens or a curved mirror.

41. The optical frequency comb setup according to claim 25, wherein in the external cavity at least one dispersive element is placed between the end facet and the mirror surface, in particular in form of a prism, a reflective grating, a phase grating or a multilayer element.

42. The optical frequency comb setup according to claim 25, wherein the laser beam with the frequency comb generated by the semiconductor cascade laser used for measurements is exited in direction to the reflective element out of the external cavity and/or in direction of the end facet of the semiconductor cascade laser at the side opposite to the side with the external cavity.

43. The optical frequency comb setup according to claim 25, wherein beside the external cavity at one side of the semiconductor cascade laser a second external cavity between a second end facet and a second reflective element on the opposite side of the external cavity is attached, wherein the laser beam for measurements with the frequency comb generated and modified by both external cavities exits the first reflective element and/or the second reflective element.

44. An external cavity added to an end facet of at least one semiconductor cascade laser, comprising a reflective element with a mirror surface being arranged spaced apart in a distance to the end facet, wherein the external cavity is arranged in the optical frequency comb setup of claim 25.
